(19) United States
(12) Patent Application Publication
(10) Pub. No.: US 2026/0358146 A1
(43) Pub. Date: Nov. 12, 2026

(54) PRINTED CIRCUIT BOARD FOR AN INDUCTIVE POSITION SENSOR PROVIDED WITH A MEANS FOR MAKING IT INSENSITIVE TO A METAL ENVIRONMENT

(71) Applicant: Schaeffler Technologies AG & Co. KG, Herzogenaurach (DE)

(72) Inventors: Alain FONTANET, Muret (FR); Jérémie BLANC, St Jean (FR)

(73) Assignee: Schaeffler Technologies AG & Co. KG, Herzogenaurach (DE)

(21) Appl. No.: 18/997,238

(22) PCT Filed: Aug. 28, 2023
(86) PCT No.: PCT/EP2023/073482

§ 371 Date: Jan. 21, 2025

(30) Foreign Application Priority Data
Sep. 2, 2022 (FR) FR2208810

(51) Int. Cl. G01D 5/20; H05K 1/16

(52) U.S. Cl. CPC G01D 5/2053; H05K 1/165; H05K 2201/10151; H05K 2201/10371

(57) ABSTRACT

A printed circuit board for an inductive sensor for measuring the position of a target. The printed circuit board includes a plurality of metal layers which are separated in pairs by respective layers of dielectric material, the printed circuit board including: at least two secondary windings, and a primary winding which surrounds the secondary windings, the windings being formed in at least two of the metal layers; and a screen, located in another of the metal layers, which is configured to make the primary winding and secondary windings insensitive to a metal environment, and consists of metal surfaces. Each of the metal surfaces is inscribed within a surface which is delimited by an orthogonal projection of the secondary windings in the plane of the screen.

### CROSS REFERENCE TO RELATED APPLICATIONS

This application is the U.S. National Phase Application of PCT International Application No. PCT/EP2023/073482, filed Aug. 28, 2023, which claims priority to French Application No. 2208810, filed Sep. 2, 2022, the contents of such applications being incorporated by reference herein.

### FIELD OF THE INVENTION

The field of the invention is that of detecting the position of a moving mechanical structure, notably a rotor of a rotary machine, using a target securely mounted on said structure.

The invention relates, more particularly, but in a non-limiting manner, to an inductive sensor configured to measure a position of a rotating part, in particular a rotary shaft or a rotor of an electrical rotating machine, in particular a motor vehicle electric motor.

### BACKGROUND OF THE INVENTION

In a manner known per se, inductive position sensors comprise a fixed part, called a “transformer”, comprising a fixed primary winding and at least two fixed secondary windings, and a movable part formed by a metal target that is rigidly connected to a mechanical part, the position of which it is desired to control.

The operating principle of such a sensor is based on an electromagnetic coupling between the primary winding and the secondary windings, and on the variations in this coupling when the position of the target varies relative to the windings.

In particular, a high-frequency alternating current is circulated in the primary winding. This current produces a magnetic field of the same frequency. This magnetic field generates induced currents in the target through the skin effect, which modify voltages induced in the secondary windings by the primary winding. Thus, the coupling between the primary winding and secondary windings varies as a function of the position of the target. Measuring the voltage at the terminals of the secondary windings therefore allows the position of the target to be determined.

The primary winding and the secondary windings are generally produced on a printed circuit board, and each consist of electrically conductive tracks mapped out on said board.

An example of such a sensor is described, for example, in patent application US 2014/0167788 A1, incorporated herein by reference. In this example, the inductive sensor is configured to measure an angular position using a primary winding and secondary windings arranged in the shape of a disk or ring.

FIGS. 1A to 1C illustrate a printed circuit board 10 of an inductive sensor according to the prior art, for measuring angular position. Here, the printed circuit board 10 comprises two metal layers 101, 102 separated by a layer 111 of dielectric material (see FIG. 1C).

The windings of the inductive sensor here comprise a primary winding 11 and two secondary windings 12a and 12b. FIG. 1A shows a first secondary winding 12a. FIG. 1B shows the primary winding 11 and a second secondary winding 12b. Each of the secondary windings 12a and 12b consists of a plurality of turns, which extend one after the other in a ring shape. Here, the turns each extend partly in the metal layer 101 and partly in the metal layer 102 of the printed circuit board 10 (with vias passing through the layer 111 of dielectric material)

The primary winding 11 is circular, with an opening for inputting and outputting an electric current. It surrounds the secondary windings 12a and 12b. It extends in at least one of the first metal layer 101 and the second metal layer 102, in the form of one or more superimposed and/or concentric circles.

The operating principle of such a sensor therefore hinges on the skin effect, which is an electromagnetic coupling between a magnetic field (here generated by the primary winding) and an electrically conductive part located in this magnetic field (here, the metal target).

The electromagnetic coupling by the skin effect can be produced with the metal target, as desired, but also with any other electrically conductive part which might be located too close to the secondary windings. If this occurs, the electromagnetic coupling with these electrically conductive parts generates induced currents which modify the voltages induced in the secondary windings. Thus, the voltages measured at the terminals of the secondary windings are affected not only by the position of the target, but also by these electrically conductive parts.

In the prior art, it is known to combine an inductive sensor with recommendations in terms of the environment, in order to avoid the presence of metal parts other than the target close to the secondary windings.

However, the constraints in terms of geometry and size prevent those constraints from being respected. The secondary windings of the inductive sensor may then be located close to electrically conductive metal parts that are distinct from the target.

Worse, these constraints can lead to the secondary windings of the inductive sensor being placed close to metal parts that are distinct from the target and lack rotational symmetry. In other words, a distance between the metal part distinct from the target and the secondary windings varies in space. These metal parts then lead to strong non-linearities in the response of the inductive sensor. The position measurement of the target is then less precise.

An aim of the present invention is to propose a solution for overcoming this disadvantage.

### SUMMARY OF THE INVENTION

This aim is met by a printed circuit board for an inductive sensor for measuring the position of a target, the printed circuit board comprising a plurality of metal layers which are separated in pairs by respective layers of dielectric material, the printed circuit board comprising:
at least two secondary windings, each formed by interlaced turns, the secondary windings extending together in at least two layers from said plurality of metal layers, called winding layers;
a primary winding surrounding the secondary windings and extending over at least one of the winding layers.

According to an aspect of the invention:
the printed circuit board further comprises a screen for making the primary winding and secondary windings insensitive to a metal environment;
the screen consists of metal surfaces located in a layer belonging to said plurality of metal layers, called a masking layer, the winding layers all extending on the same side of the masking layer; and
each of said metal surfaces is inscribed in a surface delimited by the mapping of an orthogonal projection of the secondary windings in the plane of the masking layer.

The screen according to an aspect of the invention is therefore made of metal. It is therefore able to establish an electromagnetic coupling (by the skin effect) with a magnetic field source, in particular the primary winding and secondary windings of the printed circuit board.

The screen is located in a masking layer, with the winding layers which all extend on the same side of the masking layer.

During use, the screen extends between the secondary (and primary) windings and any potential metal parts distinct from the target. More specifically, these metal parts are necessarily on the side opposite the target, because the side receiving the target is left free of any other metal part for obvious size reasons.

Thus, the electromagnetic coupling which could exist between the secondary windings and these metal parts is prevented by the presence of the screen between the two. Instead, an electromagnetic coupling is produced between the secondary windings and the screen. Thus, the screen according to an aspect of the invention can require the secondary windings to have an electromagnetic coupling with a screen, which blocks the electromagnetic coupling with other metal parts distinct from the target.

The screen according to an aspect of the invention is incorporated on the same printed circuit board as the windings. All points on the screen are thus located at the same distance from the secondary windings. In this way, a stray voltage generated at the terminals of the secondary windings by the electromagnetic coupling with the screen takes a fixed value which does not vary as a function of time. The variations in the voltage at the terminals of the secondary windings are then a function of the movement of the target only.

The incorporation of the screen in one of the layers of a multilayer printed circuit board also makes it possible to avoid problems of size and mechanical deformation that would be present with a screen consisting of a solid part distinct from the printed circuit board receiving the windings.

Due to its arrangement on the same printed circuit board as the windings, the screen is located in the immediate proximity of the secondary winding. Very high induced currents can therefore develop there, causing large energy losses.

In order to limit these induced currents, the screen according to an aspect of the invention consists of a plurality of metal surfaces, each distinct and spaced apart from one another. This division of the screen into a plurality of small surfaces prevents the development of excessively large induced currents in the screen.

An aspect of the invention can thus prevent the generation of stray measurement signals, linked to the presence of metal parts distinct from the target and close to the secondary windings. An aspect of the invention thus offers an improvement in precision of the position measurement of the target, without this resulting in a large increase in electrical energy consumption.

Finally, according to an aspect of the invention, the metal surfaces forming the screen are each inscribed within a surface delimited by an orthogonal projection of the secondary windings in the plane of the screen. Any overlap is thus avoided between the metal surfaces forming the screen and the secondary windings, for an optimum precision of position measurement by means of a voltage measurement at the terminals of the secondary windings.

This arrangement also offers other advantages, in particular:
a uniform distribution of the metal surfaces forming the screen, automatically obtained, by construction; and
an additional reduction in the inductive coupling between the primary winding and the screen, the metal surfaces forming the screen only being present along a reduced portion of the contour of the primary winding.

Preferably, the screen according to an aspect of the invention extends opposite the secondary windings, over the entire extent of said secondary windings along a movement path of the target relative to said secondary windings. This path can be circular, as shown for example in the figures, or in the shape of a rectilinear segment, or in the shape of a curved segment, or any other shape.

Preferably, the screen according to an aspect of the invention is located in one of the two outermost metal layers of the printed circuit board.

Advantageously, a gap between two neighboring metal surfaces among the metal surfaces forming the screen is less than or equal to Dₘₐₓ, where Dₘₐₓ equals 2 mm.

Preferably, metal surfaces forming the screen are distributed in a regular pattern.

Advantageously, the metal surfaces forming the screen all have the same area.

The metal surfaces forming the screen can all have the same shape.

The metal surfaces forming the screen can each be located between the orthogonal projections of different portions of turn belonging to distinct secondary windings.

Preferably, the printed circuit board according to an aspect of the invention is intended to measure angular position, and the secondary windings and the primary winding each extend in a ring shape.

Advantageously, the metal surfaces forming the screen each have the shape of a portion of a ring.

Advantageously, the printed circuit board according to an aspect of the invention comprises four metal layers, with:
a first and a second metal layer, together forming the winding layers; and
a fourth metal layer forming the masking layer, separated from the winding layers by a third metal layer.

The screen can be electrically connected to a constant-potential and non-zero voltage source. Alternatively, the screen can be electrically connected to ground.

Advantageously, the printed circuit board according to an aspect of the invention further comprises an electronic component configured to supply power to the primary winding and/or to measure voltage values at the terminals of the secondary windings, said electronic component being laterally offset relative to the primary winding and secondary windings.

Preferably, the metal surfaces forming the screen are spaced apart in pairs by a distance greater than or equal to 800 μm.

An aspect of the invention also relates to an inductive sensor for measuring the position of a target, comprising a printed circuit board according to an aspect of the invention, as well as at least one electronic component configured to measure voltage values at the terminals of the secondary windings and to deduce position measurements therefrom.

An aspect of the invention also relates to an assembly comprising an inductive sensor according to an aspect of the invention and a metal target, the inductive sensor being configured to measure the position of said target.

### BRIEF DESCRIPTION OF THE DRAWINGS

Further features and advantages of aspects of the invention will become more apparent upon reading the following description. This description is purely illustrative and should be read with reference to the appended drawings, in which:

FIG. 1A illustrates a first secondary winding of a printed circuit board according to the prior art, for an inductive sensor;

FIG. 1B illustrates a primary winding and a second secondary winding of the printed circuit board of FIG. 1A;

FIG. 1C illustrates the printed circuit board of FIG. 1A, according to a sectional view in a plane orthogonal to the plane of the windings;

FIG. 2A illustrates a first secondary winding of a printed circuit board according to an aspect of the invention;

FIG. 2B illustrates a primary winding and a second secondary winding of the printed circuit board of FIG. 2A;

FIG. 2C illustrates the screen of the printed circuit board of FIG. 2A;

FIG. 2D illustrates the printed circuit board of FIG. 2A, according to a sectional view in a plane orthogonal to the plane of the windings;

FIG. 2E illustrates the screen of the printed circuit board of FIG. 2A, as well as the orthogonal projection of the secondary windings in the same plane;

FIG. 3 illustrates the printed circuit board of FIG. 2A, according to a side view and in use with a target and in an environment comprising metal parts;

FIG. 4 illustrates the screen of a first printed circuit board variant according to an aspect of the invention;

FIG. 5 illustrates the screen of a second printed circuit board variant according to an aspect of the invention;

FIG. 6 illustrates a third printed circuit board variant according to an aspect of the invention; and

FIG. 7 illustrates an inductive sensor according to an aspect of the invention.

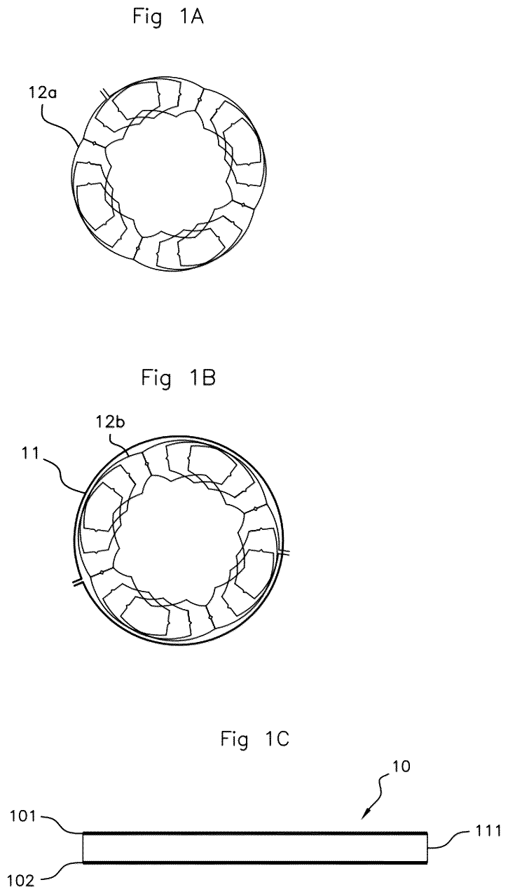

### DETAILED DESCRIPTION OF AT LEAST ONE EMBODIMENT

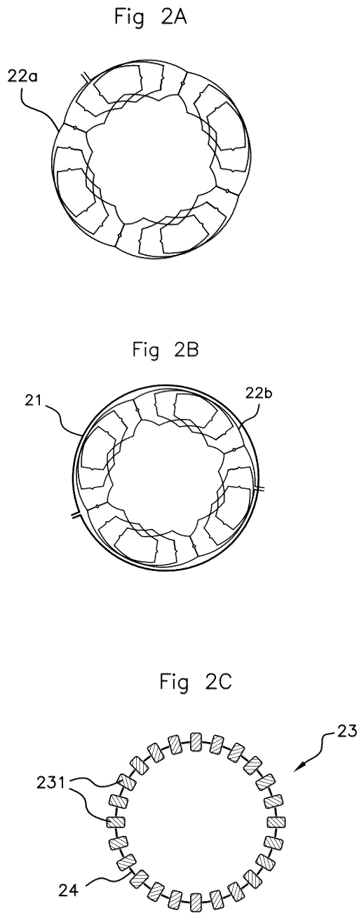

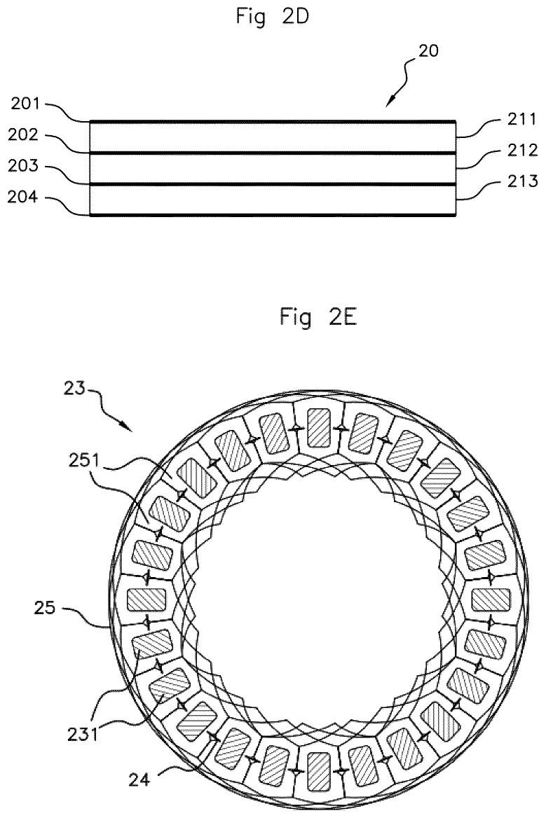

Below, with reference to FIGS. 2A to 2E, a first embodiment is described of a printed circuit board 20 according to an aspect of the invention. Here, but in a non-limiting manner, the printed circuit board is intended to be part of an angular position sensor.

In FIG. 2D, the printed circuit board 20 is represented according to a sectional view in a plane orthogonal to the windings. The printed circuit board comprises first, second, third and fourth metal layers 201, 202, 203, 204, which are separated in pairs by respective layers of dielectric material 211, 212, 213.

The windings, together forming the sensitive part of the inductive sensor, here comprise a primary winding 21 and two secondary windings 22a and 22b. In order to facilitate understanding, FIG. 2A shows a first secondary winding 22a, and FIG. 2B shows the primary winding 21 and a second secondary winding 22b.

As in the prior art described in the introduction, each of the secondary windings 22a and 22b consists of a plurality of turns, which extend one after the other in a ring shape.

Here, advantageously, the turns each extend partly in the first metal layer 201 and partly in the second metal layer 202 of the printed circuit board 20 (with vias passing through at least the layer 211 of dielectric material) Said first and second metal layers 201, 202 can be called “winding layers”.

The primary winding 21 is circular, with an opening for inputting and outputting an electric current. It surrounds the secondary windings 22a and 22b. It extends in at least one of the first metal layer 201 and the second metal layer 202, in the form of one or more superimposed and/or concentric circles.

The printed circuit board further comprises a screen 23, consisting of a plurality of distinct metal surfaces 231 (see FIG. 2C), and located in a metal layer of the printed circuit board 20, distinct from those receiving the windings. Here, the screen 23 is located in the metal layer furthest from the windings (in particular the secondary windings), in other words the fourth metal layer 204. Said fourth metal layer 204 can be called the “masking layer”.

As explained in the disclosure of an aspect of the invention, the screen 23 enables the secondary windings to be made insensitive to a metal environment distinct from the target. This involves, in particular, introducing an electromagnetic coupling between the secondary windings and a known metal element formed by the screen, this coupling replacing an electromagnetic coupling between the secondary windings and an uncontrolled metal environment.

The screen 23 extends opposite the secondary windings 22a, 22b, over the entire extent of said secondary windings along a movement path 24 of the target relative to said secondary windings, in use. Here, this circular path 24 (dotted line) and the screen 23 thus extend in a general ring shape.

Here, but in a non-limiting manner, the metal surfaces 231 forming the screen 23 all have the same area. Furthermore, these metal surfaces all have the same shape here. Here, but in a non-limiting manner, each of the metal surfaces 231 forming the screen 23 has a substantially square shape.

In addition, the metal surfaces 231 forming the screen 23 are distributed here in a regular pattern along the movement path 24 of the target. Here, but in a non-limiting manner, said metal surfaces 231 are angularly distributed in a regular manner, with a constant angular gap between two neighboring metal surfaces 231.

Below, the conditions advantageously fulfilled by the gap between two neighboring metal surfaces 231 are detailed.

Finally, FIG. 2E shows the screen 23 along with the orthogonal projection 25 of the two secondary windings in the plane of the screen 23.

Said orthogonal projection 25 delimits surfaces 251 distributed one after the other along the movement path 24 of the target. The surfaces 251 are closed surfaces, all having substantially the same shape.

If a plurality of series of surfaces of similar shapes distributed along the path 24 could be defined, the series for which the surfaces 251 have the largest area is chosen.

According to an aspect of the invention, each of the metal surfaces 231 is inscribed in a respective one of these surfaces 251. Preferably, each of said surfaces 251 receives the respective one of these metal surfaces 251.

This arrangement automatically ensures a regular distribution of the metal surfaces 231.

This arrangement also enables the metal surfaces 231 not to overlap the tracks of the secondary windings 22a, 22b, thus disturbing the electromagnetic fluxes received by the secondary windings. Thus, an optimum precision is guaranteed for the position measurement by means of a voltage measurement at the terminals of the secondary windings.

This arrangement also enables a large part of the perimeter of the primary winding to be located facing the free spaces between two of the metal surfaces forming the screen. Thus the induced currents are limited by the primary winding in the screen.

This arrangement also enables the metal surfaces 231 to bypass, by construction, metal vias passing through the entire thickness of the printed circuit board and connecting together different portions of turns of the primary, and secondary, windings, respectively.

It is noted that, according to an aspect of the invention, the distribution of the metal surfaces 231 is only a function of the arrangement of the secondary windings, independently of the shape of the target.

Advantageously, the metal surfaces 231 are each located between the orthogonal projections of portions of turn belonging to the first secondary winding 22a and the second secondary winding 22b respectively. This is linked to the interlaced arrangement of the secondary windings 22a and 22b.

In a non-limiting example, the metal surfaces 231 are, for example, copper surfaces of thickness between 34 μm and 40 μm.

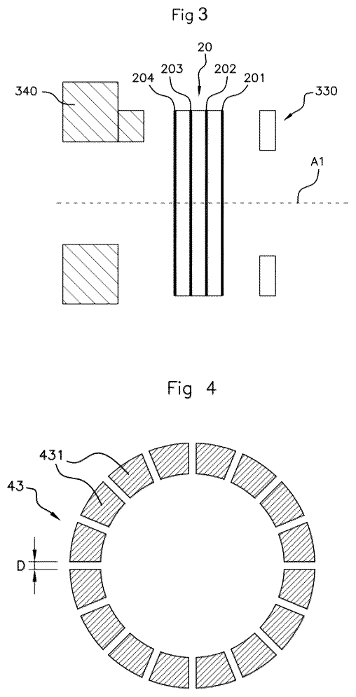

Next, schematically and with reference to FIG. 3, the printed circuit board 20 is illustrated in use with a target 330. The axis A1 schematically represents the axis of rotation of the target 330.

The first and second metal layers 201, 202, receiving the windings, are located near the target 330. The fourth metal layer 204, receiving the screen, is located on the opposite side from the target. The screen is thus located so as to be positioned between the (in particular secondary) windings and adjoining metal parts 340 which, in the absence of the screen, could disturb the signal measured at the terminals of the secondary windings.

FIG. 3 shows, in particular, that, unlike the screen according to an aspect of the invention, the adjoining metal parts 340 are at a distance from the secondary windings which varies in space, resulting in a stray signal which varies as a function of time at the secondary windings.

Next, the screen 43 of a first printed circuit board variant according to an aspect of the invention is illustrated with reference to FIG. 4.

In this variant, the metal surfaces 431 forming the screen 43 each have the shape of a portion of a ring. In particular, each metal surface has the shape of an arc of a ring, or in other words the shape of a portion of a ring delimited laterally by two radii of a disk arranged concentrically with the ring.

FIG. 4 also illustrates the gap D between two neighboring metal surfaces 431.

According to an aspect of the invention, this gap D is between:
an upper value Dₘₐₓ, beyond which there may be electromagnetic coupling between the secondary windings and an adjoining metal part distinct from the target, passing through the free spaces between the metal surfaces 341; and
a lower value Dₘᵢₙ, defined in particular by technical manufacturing constraints.

The upper value Dₘₐₓ is a function, in particular, of an expected distance between the secondary windings and said adjoining metal part distinct from the target. Under these standard conditions of use (i.e. with a distance less than 10 mm between the secondary windings and the metal part to be masked), it holds that Dₘₐₓ=2 mm, for example.

The lower value Dₘᵢₙ is for example 125 μm. It is advantageously higher, which makes it possible to relax the manufacturing constraints without impacting the desired technical effect. For example, Dₘᵢₙ=800 μm, or even Dₘᵢₙ=1 mm.

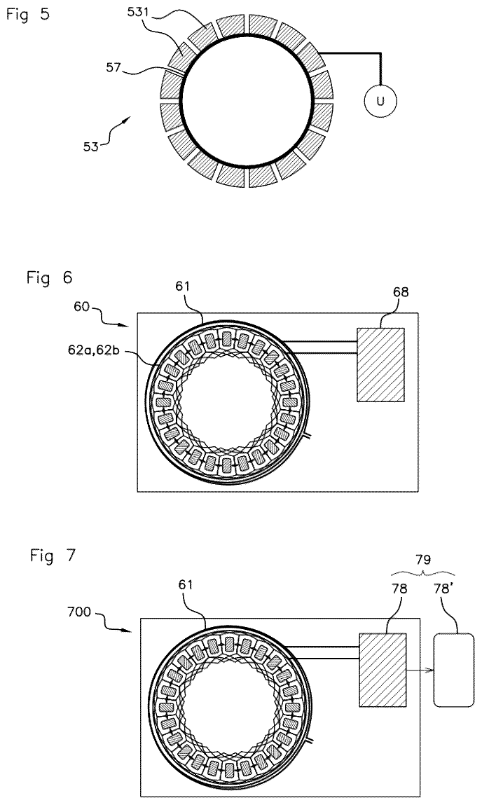

Next, the screen 53 of a second printed circuit board variant according to an aspect of the invention is illustrated with reference to FIG. 5.

In this variant, the metal surfaces 531 are all connected to the same electrical potential U. For this purpose, said metal surfaces 531 are advantageously electrically connected together by means of an electrical connection track 57. Here, but in a non-limiting manner, the electrical connection track 57 has a circular shape passing through each of the metal surfaces 531. The circle is advantageously the smallest diameter circle allowing passage through each of the metal surfaces 531 (in order to maximize a distance from the primary winding).

The electrical potential U can be a zero potential, forming the ground of an electrical circuit connected to the (primary and secondary) windings. In this case, the screen also has a protective function with respect to electromagnetic attacks (or EMC, for electromagnetic compatibility).

Alternatively, the electrical potential U is a non-zero potential, different from the ground of an electrical circuit connected to the windings.

FIG. 6 schematically illustrates a variant of a printed circuit board 60 according to an aspect of the invention, which is distinguished from the examples described above in that it further comprises an electronic component 68 configured to supply power to the primary winding 61 and/or to measure voltage values at the terminals of the secondary windings 62a, 62b.

The electronic component 68 is arranged laterally offset relative to the primary winding 61 and secondary windings 62a, 62b. In other words, the electronic component 68 is not superimposed on the windings. Viewed from above, the electronic component 68 is located beside the windings, outside of a disk delimited by the primary winding 61.

Finally, FIG. 7 illustrates an inductive sensor 700 according to an aspect of the invention, comprising a printed circuit board 70 according to an aspect of the invention, and at least one electronic component 79 configured to measure voltage values at the terminals of the secondary windings and to deduce therefrom position measurements relating to a target.

Here, the at least one electronic component 79 comprises:
a first electronic component 78, configured to supply power to the primary winding 61 and/or to measure voltage values at the terminals of the secondary windings 62a, 62b; and
a second electronic component 78′, configured to receive as input voltage values at the terminals of the secondary windings 62a, 62b, and to deduce therefrom position values of a target.

An aspect of the invention is not limited to the examples described above, and can relate to numerous other variants, with for example:
the screen produced in the third metal layer of a printed circuit board with 4 metal layers as illustrated in FIG. 2D;
a different number of metal layers in the printed circuit board, this number being, however, greater than or equal to 3;
a number of secondary coils greater than 2, for example equal to 3;
an arrangement of the windings not along a circular trajectory, but along a rectilinear or curved trajectory, or a trajectory of any other shape;
an arrangement of the windings in the shape of a disk, and not a ring, associated with an inductive sensor configured to be mounted at the end of a rotary shaft;
a screen which does not cover the secondary windings over their entire extent along the trajectory of the target, the technical effect then being obtained over only a part of the trajectory of the target;
metal surfaces forming the screen which have any shape, for example any shape allowing metal vias passing through the entire thickness of the printed circuit board to be bypassed;
a plurality of metal surfaces forming the screen, within the same surface delimited by the orthogonal projection of the secondary windings in the plane of the screen; etc.

An aspect of the invention ultimately makes it possible to produce inductive sensors with reduced dimensions and to facilitate their incorporation in strongly constrained environments, in particular in an electric vehicle motor or in electric motor control electronics.

An aspect of the invention does not have a negative impact on EMC.

In slightly different variants of an aspect of the invention, the screen can extend in the form of distinct, regularly distributed metal surfaces extending not only in a manner facing the secondary windings but also in a manner jutting out relative to the orthogonal projection of the secondary windings.

In other slightly different variants of an aspect of the invention, the screen can be formed of metal surfaces that are regularly distributed, in a pattern unrelated to the shape of the turns of the secondary windings. It is possible to have, in particular, metal surfaces covering the entirety of several neighboring turns of the secondary windings. Additionally or alternatively, the metal surfaces can be distributed in a series of concentric arcs of a circle superimposed on top of one another along an axis orthogonal to the trajectory of the target.

1. A printed circuit board for an inductive sensor for measuring the position of a target, the printed circuit board comprising a plurality of metal layers, which are separated in pairs by respective layers of dielectric material, the printed circuit board comprising:
at least two secondary windings, each formed by interlaced turns, the secondary windings extending together in at least two layers from said plurality of metal layers, called winding layers;
a primary winding surrounding the secondary windings and extending over at least one of the winding layers; and
a screen for making the primary winding and secondary windings insensitive to a metal environment; wherein:
the screen consists of metal surfaces located in a layer belonging to said plurality of metal layers, called a masking layer, the winding layers all extending on the same side of the masking layer;
each of said metal surfaces is inscribed in a surface delimited by the mapping of an orthogonal projection of the secondary windings in the plane of the masking layer; and
the metal surfaces forming the screen are each located between the orthogonal projections of different portions of turn belonging to distinct secondary windings.

2. The printed circuit board claimed in claim 1, wherein a gap between two neighboring metal surfaces of the metal surfaces forming the screen is less than or equal to Dₘₐₓ, where Dₘₐₓ equals 2 mm.

3. The printed circuit board as claimed in claim 1, wherein the metal surfaces forming the screen are distributed in a regular pattern.

4. The printed circuit board as claimed in claim 1, wherein the metal surfaces forming the screen all have the same area.

5. The printed circuit board as claimed in claim 4, wherein the metal surfaces forming the screen all have the same shape.

6. The printed circuit board as claimed in claim 1, wherein it is intended for measuring angular position, and the secondary windings and the primary winding each extend in a ring shape.

7. The printed circuit board claimed in claim 6, wherein the metal surfaces forming the screen each have the shape of a portion of a ring.

8. The printed circuit board as claimed in claim 1, further comprising four metal layers, with:
a first and a second metal layer, together forming the winding layers; and
a fourth metal layer forming the masking layer, separated from the winding layers by a third metal layer.

9. The printed circuit board as claimed in claim 1, wherein the screen is electrically connected to a constant-potential and non-zero voltage source.

10. The printed circuit board as claimed in claim 1, wherein the screen is electrically connected to ground.

11. The printed circuit board as claimed in claim 1, further comprising an electronic component configured to supply power to the primary winding and/or to measure voltage values at the terminals of the secondary windings, said electronic component being laterally offset relative to the primary winding and secondary windings.

12. The printed circuit board as claimed in claim 1, wherein the metal surfaces forming the screen are spaced apart in pairs by a distance greater than or equal to 800 μm.

13. An inductive sensor for measuring the position of a target, comprising a printed circuit board as claimed in claim 1, as well as at least one electronic component configured to measure voltage values at the terminals of the secondary windings and to deduce position measurements therefrom.

14. An assembly comprising an inductive sensor as claimed in claim 13 and a metal target, the inductive sensor being configured to measure the position of said target.

15. The printed circuit board as claimed in claim 2, wherein the metal surfaces forming the screen are distributed in a regular pattern.
